(19) United States
(12) Patent Application Publication
(10) Pub. No.: US 2005/0130376 A1
(43) Pub. Date: Jun. 16, 2005

(54) Method for manufacturing flash device

(75) Inventor: Hyeon Sang Shin, Kyungki-Do (KR)

Correspondence Address: MARSHALL, GERSTEIN & BORUN LLP, 6300 SEARS TOWER, 233 S. WACKER DRIVE, CHICAGO, IL, 60606, US

(73) Assignee: HYNIX SEMICONDUCTOR INC., Kyungki-Do (KR)

(21) Appl. No.: 10/878,338

(22) Filed: Jun. 28, 2004

(30) Foreign Application Priority Data
Dec. 15, 2003 (KR) 2003-91652

(51) Int. Cl. H01L 21/336

(52) U.S. Cl. 438/264

(57) ABSTRACT

The present invention relates to a method for manufacturing a flash device. After a gate electrode for a flash device is formed, an EFH of an isolation film is reduced through a predetermined etch process. It is therefore possible to reduce the step of a barrier film for protecting an isolation film. Moreover, by reducing the step of the barrier film, it is possible to prevent a condition that a contact is not opened due to the step of the barrier film upon formation of a source line contact and a drain contact. Furthermore, it is possible to sufficiently reduce an EFH of an isolation film through a sufficient etch using a mask through which only a cell region is opened.

### BACKGROUND

1. Field of the Invention

The present invention relates to a method for manufacturing a flash device, and more specifically, to a method for controlling an effective field oxide (FOX) height (hereinafter, referred to as “EFH”) in a flash device.

2. Discussion of Related Art

Generally, in a flash device, an ion implantation process is performed to a wafer, prior to forming a gate oxide film and a first polysilicon film and pattering the gate oxide film and the first polysilicon film to define isolation regions in which isolation films are formed, unlike a DRAM wherein an isolation film is formed before performing a series of ion implantation processes and forming a gate oxide film and a gate electrode. In the flash device, it is required that the EFH, a height of a top surface of the isolation film, be always kept higher than the first polysilicon film. Thus, the EFH in the flash device is kept higher than that in the DRAM.

FIG. 1A to FIG. 1D show SEM photographs for explaining conventional problems.

Referring to FIG. 1A to FIG. 1D, in case of a NAND flash device using a dual gate, it is required that the EFH be kept based on a gate insulating film (about 350 Å) for a high voltage device in a peripheral circuit region. In a region where a tunnel oxide film (about 80 Å) is formed, the EFH is kept about 270 Å or higher being its step. For this reason, the EFH of a cell region is kept higher about 570 to 770 Å than a DRAM (see FIG. 1A and FIG. 1B).

Before an interlayer insulating film is deposited, a field oxide barrier nitride film is formed in order to prevent damage of an isolation film due to misalignment of a contact. At this time, the barrier nitride film is deposited more thickly at the step where the EFH is high (see FIG. 1C). Due to this, in case where a source line contact and a drain contact are formed by means of subsequent processes, there occurs a contact not-open condition that the barrier nitride film below the contact is not well stripped (see FIG. 1D). In order to solve this, it is required that an etch target be high upon etching of the contact. This results in problems that damage of the silicon substrate below the contact is increased and damage of the top of the silicon substrate is additionally generated due to the lack in the margin of a photoresist pattern.

### SUMMARY OF THE INVENTION

The present invention is contrived to solve the problems and an object of the present invention is to provide a method for manufacturing a flash device wherein the step of a barrier film for protecting a field oxide film is removed through control of the EFH.

According to an embodiment of the present invention, there is provided a method for manufacturing a flash device, comprising the steps of: sequentially forming a tunnel oxide film, a first conductive film and a hard mask film on a semiconductor substrate; etching the hard mask film, the first conductive film, the tunnel oxide film and the semiconductor substrate to form a trench, filling the trench with a field oxide film and then polishing the trench; removing the hard mask film to form an isolation film of a shape wherein the isolation film is projected at a predetermined height from the semiconductor substrate; depositing a second conductive film on the entire structure and patterning the second conductive film to form a floating gate electrode; depositing a dielectric film, a third conductive film and a metal film on the entire structure and then etching the metal film, the third conductive film, the dielectric film and the floating gate electrode to form a gate electrode for the flash device; implementing an ion implantation process to form a source/drain; implementing a predetermined etch process to etch a portion of the projected isolation film; and forming a barrier film for protecting the isolation film on the entire structure.

Preferably, the method may further comprise the steps of, after the step of forming the barrier film, forming a first interlayer insulating film on the entire structure and then patterning the first interlayer insulating film and the barrier film to form a source line contact; filling the source line contact with a metal film and then polishing the source line contact to form a source line plug; forming a second interlayer insulating film on the entire structure and then patterning the second interlayer insulating film, the first interlayer insulating film and the barrier film to form a drain contact; and filling the drain contact with a metal film and then polishing the drain contact to form a drain contact plug.

Preferably, the etch process may use a spin etcher of a dip type or a single wafer type and may include removing the isolation film in thickness of 200 to 800 Å using a HF and/or BOE solution whose ratio is 50:1 to 300:1.

Preferably, the step of implementing the predetermined etch process to etch a portion of the projected isolation film may comprise the steps of: forming a photoresist pattern through which a cell region is opened; and consecutively positioning an etchant apparatus and a sulfuric acid/peroxide bath and then removing the isolation film and the photoresist pattern in a single apparatus, wherein the isolation film is removed in thickness of 400 to 700 Å.

### BRIEF DESCRIPTION OF THE DRAWINGS

FIG. 1A to FIG. 1D show SEM photographs for explaining conventional problems;

FIG. 2a to FIG. 2e are cross-sectional views for explaining a method for manufacturing a flash device according to the present invention;

FIG. 3 shows a SEM photograph after the barrier film is formed according to the present invention; and

FIG. 4 shows a SEM photograph after the source line contact is formed according to the present invention.

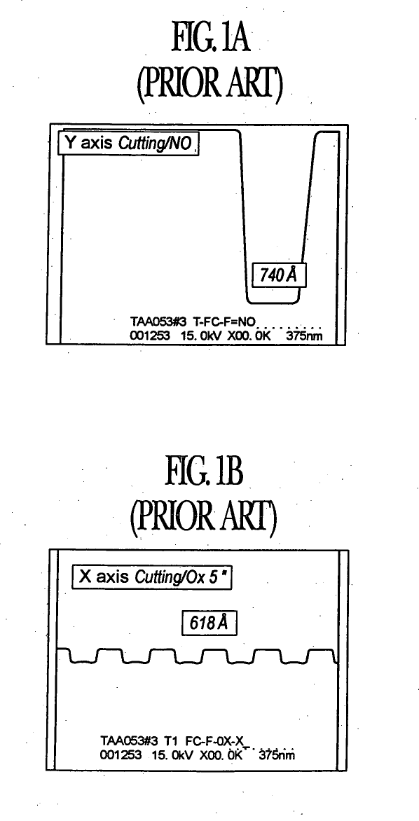

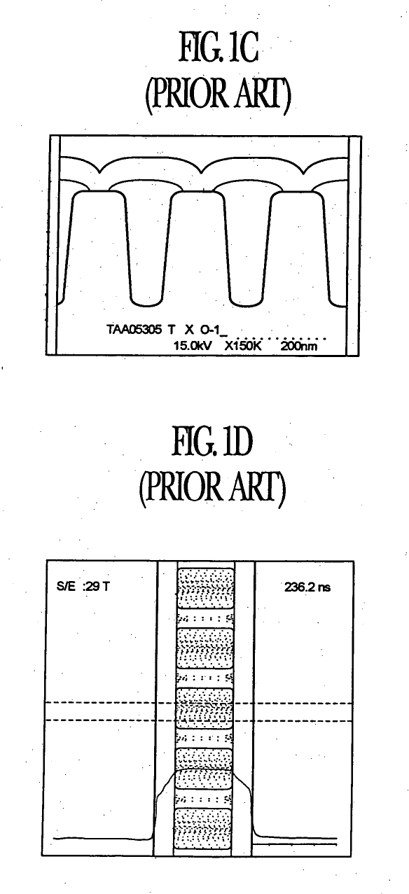

### DETAILED DESCRIPTION OF PREFERRED EMBODIMENTS

Now the preferred embodiments according to the present invention will be described with reference to the accompanying drawings. Since preferred embodiments are provided for the purpose that the ordinary skilled in the art are able to understand the present invention, they may be modified in various manners and the scope of the present invention is not limited by the preferred embodiments described later. Like reference numerals are used to identify the same or similar parts.

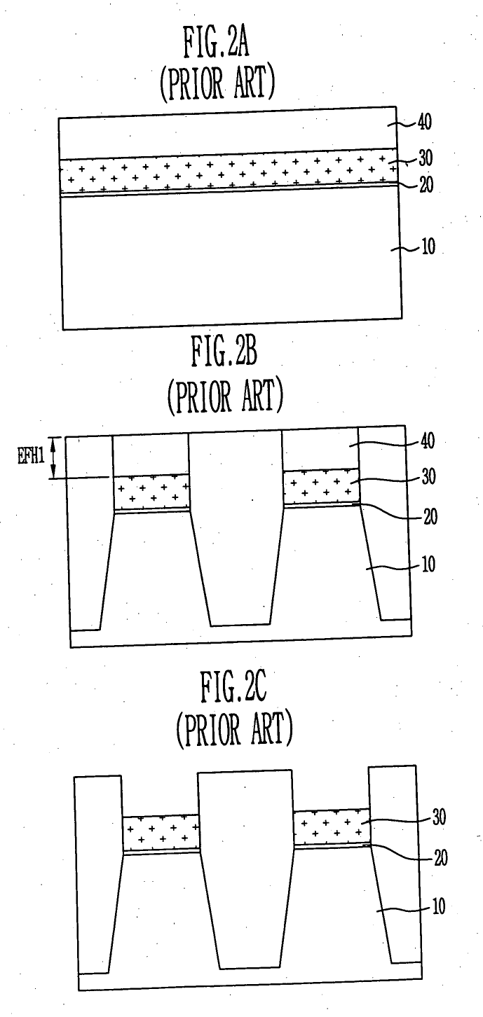

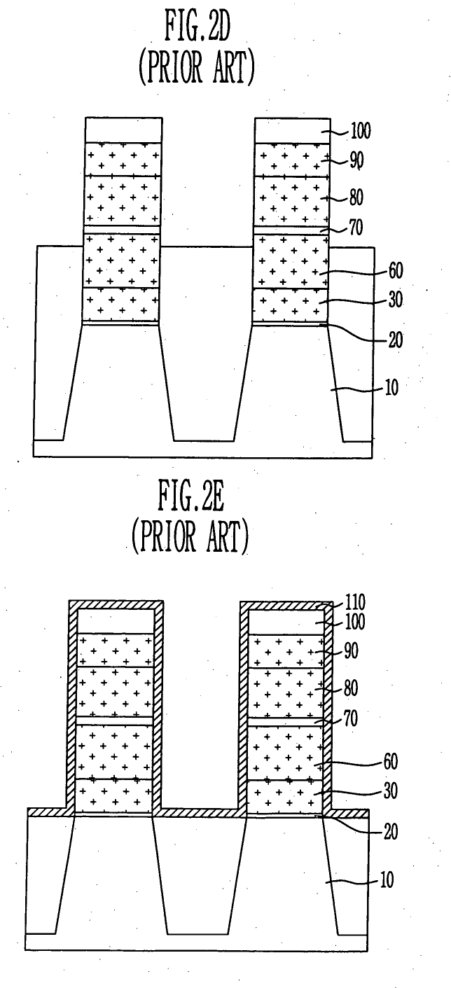

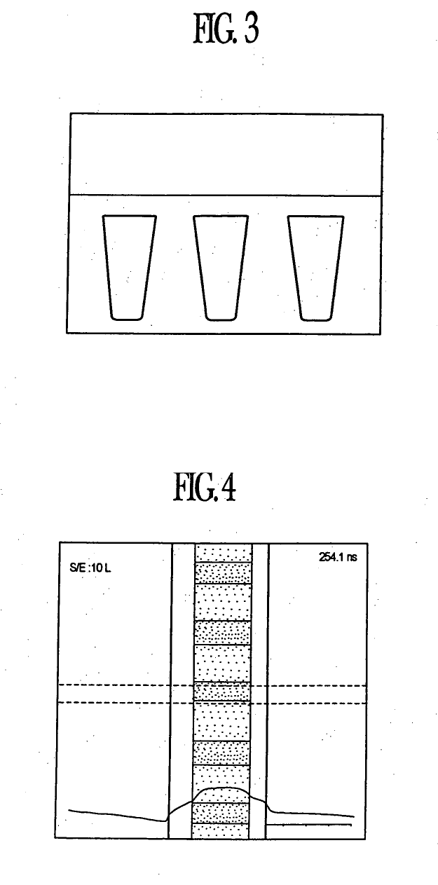

FIG. 2A to FIG. 2E are cross-sectional views for explaining a method for manufacturing a flash device according to the present invention.

Referring to FIG. 2A, a well and an ion layer for controlling the threshold voltage (not shown) are formed in a semiconductor substrate 10 through ion implantation for controlling the well and the threshold voltage. The well may be a triple well, an N well and a P well. A tunnel oxide film 20, a first conductive film 30 and a hard mask film 40 are formed on the semiconductor substrate 10 in which the well and the ion layer for controlling the threshold voltage are formed.

In the above, before the tunnel oxide film 20 is deposited, a pre-treatment cleaning process may be performed using SC-1 (Standard Cleaning-1) comprising DHF (dilute HF) where the mixing ratio of H₂O and HF is 50:1, NH₄OH, H₂O₂ and H₂O, or SC-1 comprising BOE (buffered oxide etch) where the mixing ratio of NH₄F and HF is 100:1 to 300:1, NH₄OH, H₂O₂ and H₂O.

It is preferred that the tunnel oxide film 20 is formed in thickness of 70 to 100 Å in a dry or wet oxidization mode at a temperature of 750 to 850° C.

It is preferable that the first conductive film 30 is formed using a polysilicon film, which will be used as some of a floating gate through a subsequent process. The first conductive film 30 is preferably formed in thickness of 300 to 500 Å using a doped or undoped polysilicon film by means of a chemicals vapor deposition (CVD) method, a low pressure CVD (LPCVD) or a plasma enhanced CVD (PECVD) method or an atmospheric pressure CVD (APCVD) method.

The hard mask film 40 is preferably formed using a material film of a nitride film series so that it protects an underlying structure upon subsequent etching of a trench. The hard mask film 40 may be formed in thickness of 900 to 1200 Å using a nitride film by means of the LP-CVD method. A SiON film may be used as the hard mask film 40.

Referring to FIG. 2B and FIG. 2C, a photoresist pattern (not shown) for forming a trench for isolation is formed. The hard mask film 40, the conductive film 30, the tunnel oxide film 20 and the semiconductor substrate 10 are then sequentially etched by means of an etch process using the photoresist pattern as an etch mask, forming the trench for isolation (not shown).

After a photoresist pattern is stripped through a predetermined strip process, a sidewall oxidization process for compensating for etch damage at the trench sidewall is implemented. After a field oxide film is deposited on the entire structure, a polishing process using the hard mask film 40 as a stop layer is performed. The hard mask film 40 is then removed to form an isolation film 50.

In the above, the field oxide film is formed by depositing a HDP oxide film having a thickness of 4000 to 6000 Å on the entire structure in which the trench is formed, considering the margin of a subsequent polishing process. At this time, it is preferred that the HDP oxide film is filled so that an empty space is not formed therein. The polishing process is preferably a chemicals mechanical polishing method using the hard mask film 40 as a stop layer. Further, the strip process preferably includes stripping the remaining hard mask film 40 using a phosphoric acid (H₃PO₄) solution.

The isolation film 50 formed through the aforementioned polishing process is projected at a predetermined height from the surface of the semiconductor substrate 10 (see EFH1 in FIG. 2b). The projected height of the isolation film 50 indicates an effective FOX height (EFH).

Referring to FIG. 2D, a second conductive film 60 is formed on the entire structure. The second conductive film 60 is patterned to form a floating gate electrode having first and second conductive films 30 and 60. A dielectric film 70, a third conductive film 80 for a control gate electrode, a metal film 90 and a gate patterning film 100 are formed on the entire structure. The gate patterning film 100, the metal film 90, the third conductive film 80 and the dielectric film 70 are etched by means of a patterning process, thus forming a control gate electrode. The floating gate electrode is then isolated to form a gate electrode of the flash device, which is composed of the floating gate electrode and the control gate electrode.

The second conductive film 60 is preferably formed using the same polysilicon film as the first conductive film 30.

The floating gate electrode is formed as follows. After the second conductive film 60 is formed, a nitride film (not shown) is deposited. A photoresist pattern (not shown) for forming the floating gate electrode is then formed on the nitride film. The nitride film and the second conductive film 60 are then etched by means of an etch process using the photoresist pattern as an etch mask. Further, after the nitride film is formed, an underlying anti-reflective film (not shown) may be covered. The nitride film is then removed by means of a predetermined etch process.

The dielectric film 70 of the ONO structure is formed on the entire structure. It is preferable that the third conductive film 80 is formed using the same polysilicon film as the first and second conductive films 30 and 60. It is preferred that the metal film 90 is formed using a tungsten silicide film or a tungsten film and the gate patterning film 100 is formed using a material film of a nitride film series.

In the above, after the photoresist pattern is formed on the gate patterning film 100, the gate patterning film 100 is patterned. The metal film 90, the third conductive film 80 and the dielectric film 70 are then patterned by means of a gate etch process using the patterned gate patterning film as an etch mask, so that the control gate electrode is formed. The second conductive film 60 is then etched to isolate the floating gate electrode, thereby forming the gate electrode of the flash device.

Hereinafter, a source/drain (not shown) may be formed using a predetermined ion implantation process. Furthermore, a gate sidewall oxidization process for compensating for damage due to the gate etch may be performed.

FIG. 3 shows a SEM photograph after a barrier film is formed according to the present invention.

Referring to FIG. 2E, FIG. 3 and FIG. 4, a portion of the projected isolation film 50 is etched by means of a predetermined etch process. A barrier film 110 for protecting the isolation film 50 in a contact formation process is then formed. By etching the projected isolation film 50, it is possible to reduce the step between the active region and the isolation region and thus to form the barrier film 10 with no step.

As described above, the EFH of the isolation film 50 is about 200 to 800 Å considering the height of the gate oxide film for the high voltage device in the peripheral circuit region. The EFH of the cell region is about 270 Å. It is thus preferred that the isolation film 50 is removed in a thickness that does not affect the shape that the contact is not opened according to technology. It is preferred that the projected isolation film 50 region is removed with the target of the etch process set 200 to 800 Å. Moreover, in the wet etch process, it is effective to remove the projected isolation film 50 after the gate electrode for the flash device is formed because some regions of the second conductive film 60 is formed to have a shape wherein they are extended over the isolation film 50.

Furthermore, when being formed together with transistors in the peripheral circuit, a gate oxide film of a dual structure is formed. It is preferred that the gate oxide film of the dual structure is formed by means of a wet etch process after a mask through which the cell region is opened is used, if the present invention is applied due to its difference in thickness.

In the event that only the cell region is experienced by the wet etch using the mask through which the cell region is opened, it is preferred that an accurate etch is performed with an etch target that the isolation film 50 is removed in thickness of about 400 to 700 Å. If the mask through which the cell region is opened is not used, it is preferred that the wet etch process is implemented with an etch target that the isolation film 50 is removed in thickness of about 200 to 400 Å, considering the gate oxide film for the high voltage device.

The etch process may be performed using HF and/or BOE solution being an oxide etchant. It is preferred that a spin etcher of a dip type or a single wafer type is used as the etch process. In the station of the dip type, the wafer top is first immersed into chemicals. Thus, an etch time of the water top is relatively lengthened compared to that of the wafer bottom. If the etch rate of the oxide film is high, it is disadvantageous to uniformly control the EFH within the wafer. If the etch rate of the oxide film is too low, the progress time is lengthened. It is thus preferred that the dilution ratio of chemicals and water is 50:1 to 300:1.

In the event that the mask through which the cell region is opened is formed using a photoresist pattern, it is preferable that a wet etch is performed in a single apparatus where an etchant bath and a sulfuric acid/peroxide bath are consecutively positioned and a photoresist strip process is consecutively implemented.

It is preferred that a material film of a nitride film series is formed on the entire structure as the barrier film 110 in order to protect the isolation film 50.

A first interlayer insulating film (not shown) for protection of an underlying structure and electrical insulation among the layers is formed on the entire structure. The first interlayer insulating film and the barrier film 110 are then removed by means of a predetermined patterning process, thus forming a contact (not shown) for forming a source line. At this time, a condition that the contact region is not opened can be prevented because the step of the barrier film 110 due to the isolation film 50 does not exist. The contact is filled with a conductive film and is then polished to form a source line plug (not shown). Next, a second interlayer insulating film (not shown) is formed on the entire structure. The second interlayer insulating film, the first interlayer insulating film and the barrier film 110 are patterned to form a contact plug (not shown). At this time, a condition that the contact region is not opened can be prevented because an underlying barrier film with no step is formed. Thus, since a sufficient etch margin can be secured in an etch process for forming a source line contact and a drain contact, it is possible to prevent an underlying semiconductor substrate from being damaged.

According to the present invention described above, after a gate electrode for a flash device is formed, an EFH of an isolation film is reduced through a predetermined etch process. It is therefore possible to reduce the step of a barrier film for protecting an isolation film.

Moreover, by reducing the step of the barrier film, it is possible to prevent a condition that a contact is not opened due to the step of the barrier film upon formation of a source line contact and a drain contact.

Furthermore, it is possible to sufficiently reduce an EFH of an isolation film through a sufficient etch using a mask through which only a cell region is opened.

1. A method for manufacturing a flash device, comprising the steps of:
sequentially forming a tunnel oxide film, a first conductive film and a hard mask film on a semiconductor substrate;
etching the hard mask film, the first conductive film, the tunnel oxide film and the semiconductor substrate to form a trench, filling the trench with a field oxide film and then polishing the trench;
removing the hard mask film to form an isolation film of a shape wherein the isolation film is projected at a predetermined height from the semiconductor substrate;
depositing a second conductive film on the entire structure and patterning the second conductive film to form a floating gate electrode;
depositing a dielectric film, a third conductive film and a metal film on the entire structure and then etching the metal film, the third conductive film, the dielectric film and the floating gate electrode to form a gate electrode for the flash device;
implementing an ion implantation process to form a source/drain;
implementing a predetermined etch process to etch a portion of the projected isolation film; and
forming a barrier film for protecting the isolation film on the entire structure.

2. The method as claimed in claim 1, further comprising the steps of, after the step of forming the barrier film,
forming a first interlayer insulating film on the entire structure and then patterning the first interlayer insulating film and the barrier film to form a source line contact;
filling the source line contact with a metal film and then polishing the source line contact to form a source line plug;
forming a second interlayer insulating film on the entire structure and then patterning the second interlayer insulating film, the first interlayer insulating film and the barrier film to form a drain contact; and
filling the drain contact with a metal film and then polishing the drain contact to form a drain contact plug.

3. The method as claimed in claim 1, wherein the etch process includes using a spin etcher of a dip type or a single wafer type and removing the isolation film in thickness of 200 to 800 Å using a HF and/or BOE solution whose ratio is 50:1 to 300:1.

4. The method as claimed in claim 1, wherein the step of implementing the predetermined etch process to etch a portion of the projected isolation film comprises the steps of:
forming a photoresist pattern through which a cell region is opened; and
consecutively positioning an etchant apparatus and a sulfuric acid/peroxide bath and then removing the isolation film and the photoresist pattern in a single apparatus, wherein the isolation film is removed in thickness of 400 to 700 Å.
